(19) United States
(12) Patent Application Publication
(10) Pub. No.: US 2012/0168890 A1
(43) Pub. Date: Jul. 5, 2012

(54) IMAGE SENSOR STRUCTURE

(76) Inventors: Yu Hin Desmond Cheung, Grand Cayman (KY); Kihong Kim, Grand Cayman (KY); Yang Wu, Grand Cayman (KY)

(21) Appl. No.: 12/984,589

(22) Filed: Jan. 4, 2011

(51) Int. Cl. H01L 31/05

(52) U.S. Cl. 257/435; 257/E31.11

(57) ABSTRACT

An image sensor structure, which comprises: a pixel; a first metal line; a second metal line, located under the first metal line; a conductive region, located under the second metal line; and at least one dummy contact, provided between the second metal line and the conductive region, wherein the second metal line and the conductive region are not electrically connected to each other via the dummy contact

### BACKGROUND OF THE INVENTION

1. Field of the Invention

The present invention relates to an image sensor structure, and particularly relates to an image sensor structure utilizing at least a dummy via or al least a dummy contact.

2. Description of the Prior Art

An image sensor may suffer from optical crosstalk, which degrades the image quality (resolution and color fidelity). Optical crosstalk here refers to light intended for a particular pixel enters into neighboring pixels. However, optical crosstalk can not be trivial from the pixel layout since the pixel layout is 2D while the real structure is 3D. Metal routings are usually drawn to improve optical crosstalk issue such that optical crosstalk can be controlled and at the same time sensitivity tradeoff is minimized. However, large gaps still exist between polysilicon and different metal routings, thus optical signal may “leak” or “crosstalk” to its neighbor.

Contacts and vias can help reduce optical cross talk but they are utilized only where an interconnect between two layers is necessary. Accordingly, there is usually only a few contacts/vias and they might not exist in optimal locations to reduce optical crosstalk.

FIG. 1 is a top view diagram illustrating a prior art image sensor structure. As shown in FIG. 1, a plurality of contacts 101, 103, 105 and 107 (only parts of them are marked) are provided between metal lines 109 and 111. Also, a plurality of contacts 109, 111, 113 and 115 (only parts of them are marked) are provided between the metal line 109 and conductive regions (not shown) such as a diffusion region or a poly region.

FIG. 2 is a section view of the image sensor structure in FIG. 1. In FIG. 2, FIG. 2(a) is a section view corresponding to cross section line AA′ and FIG. 2(b) is a section view corresponding to the cross section line BB′. As shown in FIG. 2(a), at the right side, the optical signal NL from a neighbor pixel can be blocked since there is a contact 201 located between metal lines 203 and 205. However, at the left side, the optical signal NL from a neighbor pixel can not be blocked and will enter the pixel 211 to generate optical cross talk, since there is no contact located under the metal lines 207 and 209. Also, desired optical signal L, which is represented by dotted lines, may lose due to the incident angle.

Similarly, at the right side of FIG. 2(b), the optical signal NL from a neighbor pixel can be blocked since there is a via 213 located between the metal line 215 and the diffusion region 217. However, at the left side, the optical signal NL from a neighbor pixel can not be blocked and will enter the pixel 219 to generate optical cross talk, since there is no via located under the metal lines 221 and 223. Also, desired optical signal L may lose due to the incident angle.

### SUMMARY OF THE INVENTION

One embodiment discloses an image sensor structure, which comprises: a pixel; a first metal line; a second metal line, located under the first metal line; at least one dummy via, provided between the first metal line and the second metal line, wherein the first metal line and the second metal line are not electrically connected to each other via the dummy via.

Another embodiment discloses an image sensor structure, which comprises: a pixel; a first metal line; a second metal line, located under the first metal line; a conductive region, located under the second metal line; and at least one dummy contact, provided between the second metal line and the conductive region, wherein the second metal line and the conductive region are not electrically connected to each other via the dummy contact.

According to above-mentioned embodiments, dummy vias and dummy contacts can be provided at suitable locations to avoid undesired neighbor optical signals entering pixels. Also, the desired optical signal can be reflected to the pixel. Therefore, the issue described in the prior art can be improved.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a top view diagram illustrating a prior art image sensor structure.

FIG. 2 is a cross section view of the image sensor structure in FIG. 1.

FIG. 3 is a top view diagram illustrating an image sensor structure according to one embodiment of the present application.

FIGS. 4, 5, 6 are examples for cross section views of the image sensor structure shown in FIG. 3.

FIG. 7 is a top view diagram illustrating an image sensor structure according to one embodiment of the present application.

### DETAILED DESCRIPTION

Certain terms are used throughout the description and following claims to refer to particular components. As one skilled in the art will appreciate, electronic equipment manufacturers may refer to a component by different names. This document does not intend to distinguish between components that differ in name but not function. In the following description and in the claims, the terms “include” and “comprise” are used in an open-ended fashion, and thus should be interpreted to mean “include, but not limited to . . . ”.

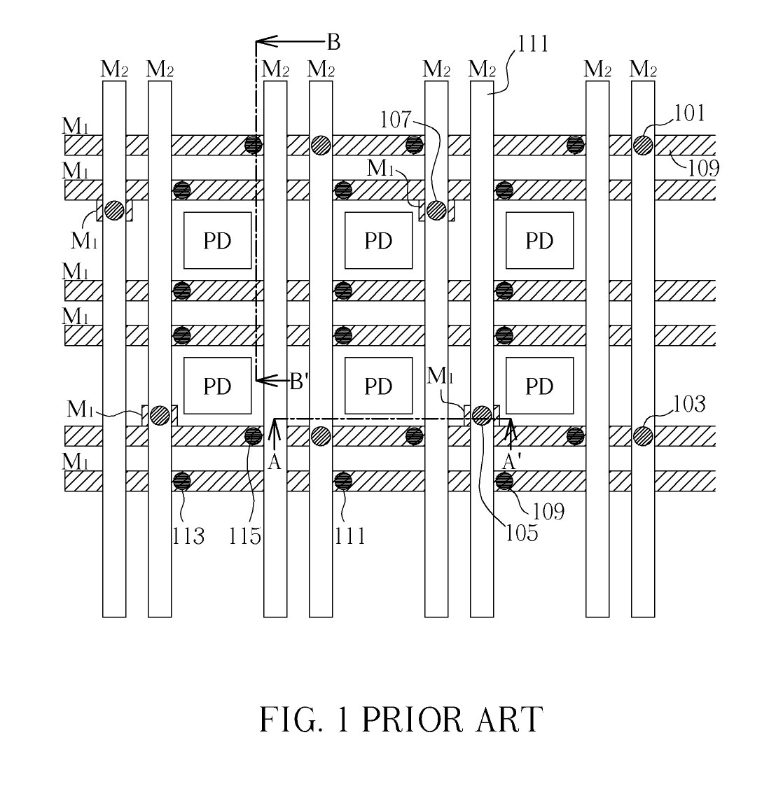

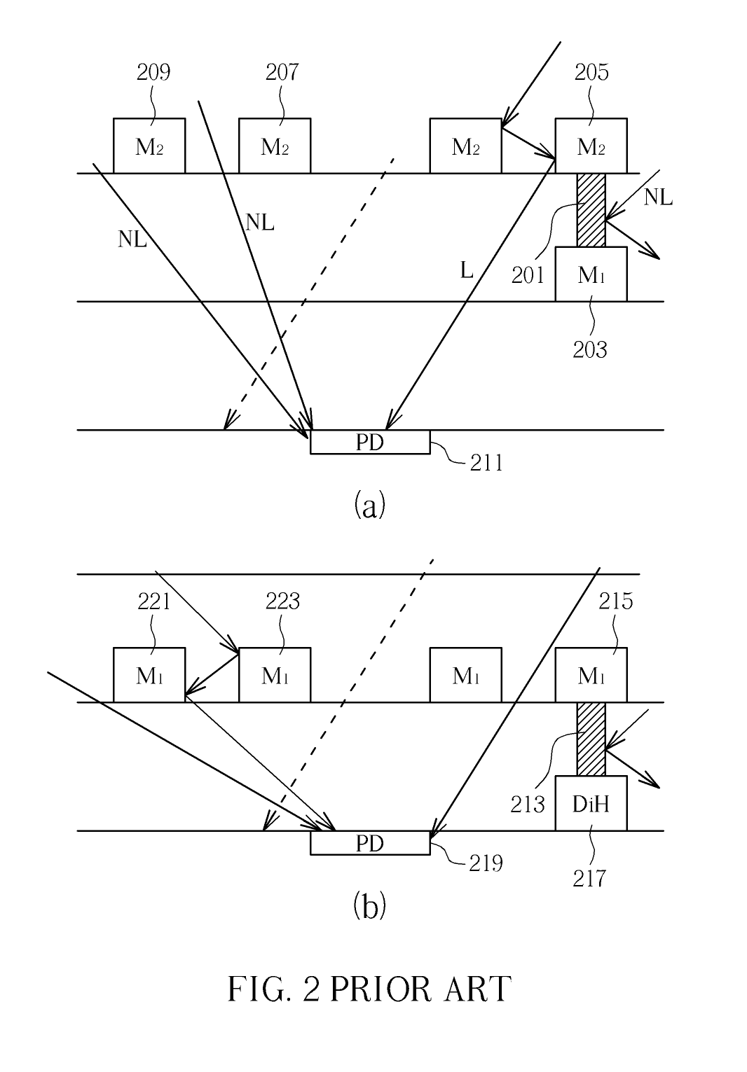

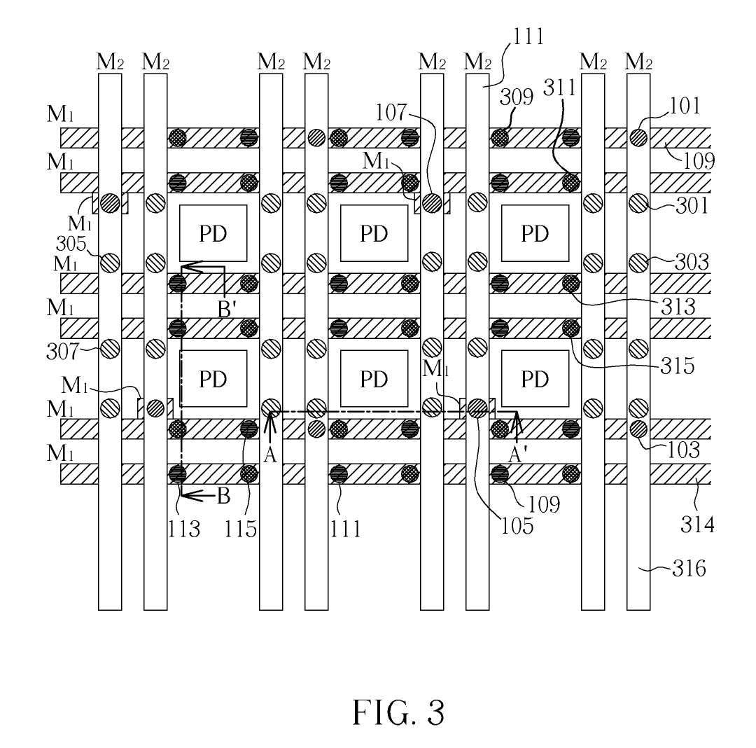

FIG. 3 is a top view diagram illustrating an image sensor structure according to one embodiment of the present application. Comparing with the top view shown in FIG. 1 and FIG. 3, FIG. 3 further comprises dummy vias, which are symbolized as circles include right slant lines such as dummy vias 303, 305 and 307, and dummy contacts, which are symbolized as circles including two direction slant lines such as dummy contacts 313 and 315, besides the vias and contacts shown in FIG. 1. Please note that the marks utilized in FIG. 3 to indicate dummy contacts and dummy vias are only for the convenience to identify vias, contacts, dummy vias and dummy contacts, and do not mean to limit the structures or materials of dummy vias and dummy contacts.

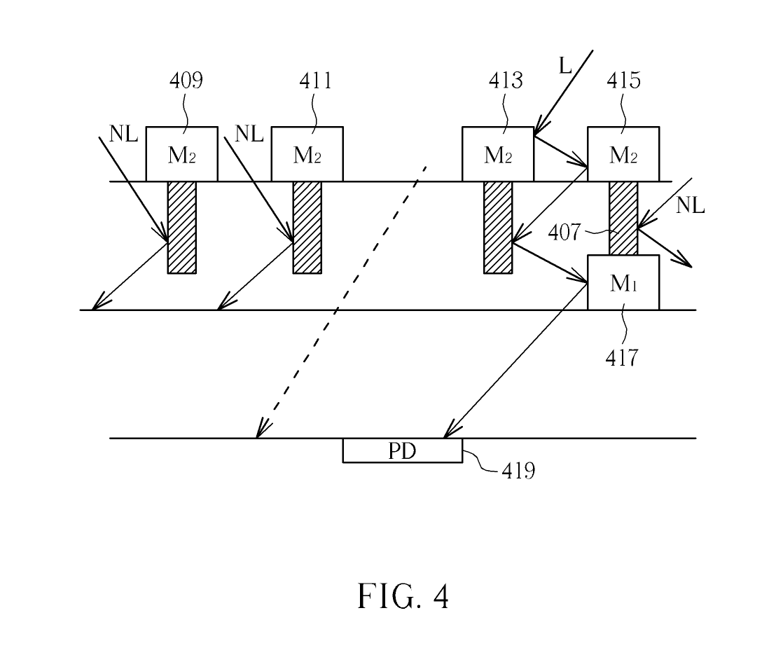

Dummy vias are vias that are provided between metal layers 314 and 316, but the metal layers 314 and 316 are not electrically connected to each other via dummy vias. FIG. 4 is an example for a cross section view of the image sensor structure shown in FIG. 3. The cross section view shown in FIG. 4 corresponds to the cross section line AA′ shown in FIG. 3. As shown in FIG. 4, a plurality of dummy vias 401, 403, and 405 are provided between the upper metal lines 409-415 and the lower metal line 417, and the dummy vias 401, 403, and 405 are only connected to upper metal lines 409-413 but not connected to the lower metal line 417. Please note that the device 407 shown in FIG. 4 is a via rather than a dummy via. Accordingly, the upper metal lines 409-413 are not electrically connected to the lower metal line 409 via the dummy vias 401, 403, and 405. In the structure shown in FIG. 4, the desired optical signal L can still be reflected by the dummy via 405 to enter the pixel 419, but the neighbor optical signal NL will be blocked by the dummy vias 401 and 403. Thus, the problem disclosed in prior art can be solved.

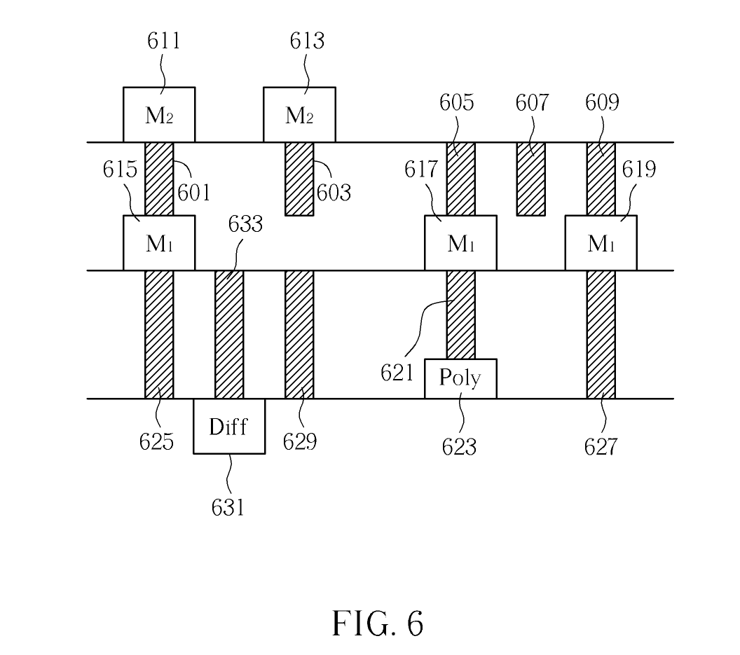

Besides the structure shown in FIG. 4, the distribution of the dummy vias can be as shown in FIG. 6. In the structure shown in FIG. 6, the via 601 is connected between the upper metal line 611 and the lower metal line 615. Also, the dummy via 603 is still connected to the upper metal line 613. However, the dummy vias 605 and 609 are only connected to the lower metal lines 617 and 619. Also, the dummy via 607 connects to neither the upper metal lines 611 and 613 nor the lower lines 615, 617,619. Accordingly, the dummy vias can be designed to be connected to the lower metal line, or connected to neither the upper metal line nor the lower metal line.

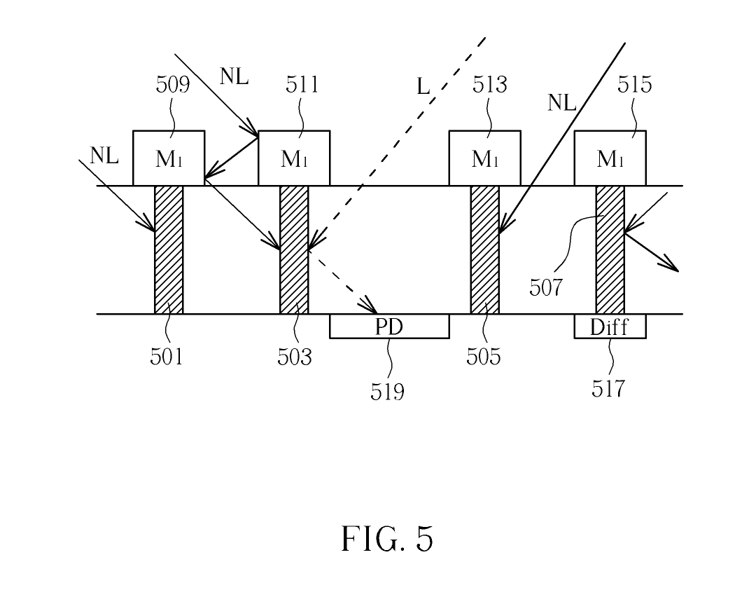

FIG. 5 is an example for a cross section view of the image sensor structure shown in FIG. 3. The cross section view shown in FIG. 5 corresponds to the cross section line BB′ shown in FIG. 3.

As shown in FIG. 5, a plurality of dummy contacts 501, 503, and 505 are provided between the lower metal lines 509-515 and the conductive region 517 (diffusion region in this embodiment), and the dummy contacts 501, 503, and 505 are only connected to lower metal lines 509-513 but not connected to the conductive region 517. Please note that the device 507 shown in FIG. 5 is a contact rather than a dummy contact. Accordingly, the lower metal lines 509-515 are not electrically connected to the conductive region 517 via dummy contacts 501-505. In the structure shown in FIG. 5, the desired optical signal L can be reflected by the dummy contact 503 to enter the pixel 519, but the neighbor optical signal NL will be blocked by the dummy contacts 501, 503 and 505. Thus, the problem disclosed in prior art can be solved.

Besides the structure shown in FIG. 5, the distribution of the dummy contacts can be as shown in FIG. 6. In the structure shown in FIG. 6, the contact 621 is connected between the lower metal line 617 and the conductive region 623 (diffusion region in this embodiment). Also, the dummy contacts 625 and 627 are still connected to the lower metal line 619. However, the dummy contact 633 is only connected to the conductive region 631. Also, the dummy contact 629 connects to neither the lower metal lines 615, 617, 619 nor the conductive region 631. Accordingly, the dummy vias can be designed to be only connected to the conductive region, or connected to neither the lower metal line nor the conductive region. Please note that the structure shown in FIG. 6 also indicates that the dummy vias and the dummy contacts can be jointly utilized in the image sensor structure.

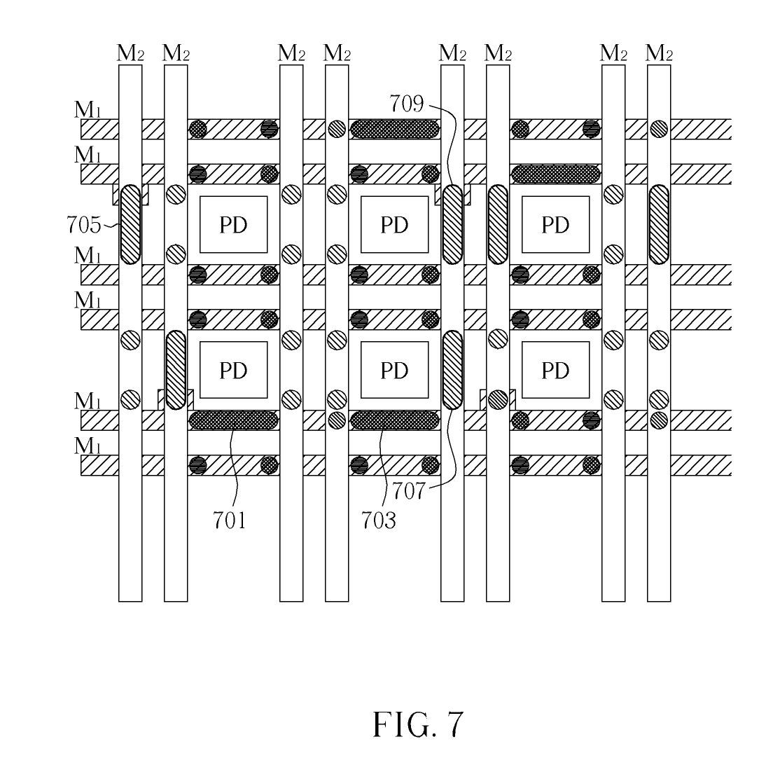

The dummy contact can be extended to a dummy contact side wall, and the dummy via can be extended to a dummy via side wall. FIG. 7 is a top view diagram illustrating an image sensor structure according to another embodiment of the present application. As shown in FIG. 7, a dummy contact and a contact can be combined to form a dummy contact side wall such as the dummy contact side wall 705. Also, two dummy vias can be combined to form a dummy via side wall such as the dummy via side walls 707 and 709. Additionally, two dummy contacts can be combined to form a dummy contact side wall such as the dummy contact side walls 701 and 703. Via the structure shown in FIG. 7, the function of the dummy contacts or vias can also be reached.

According to above-mentioned embodiments, dummy vias and dummy contacts can be provided at suitable locations to avoid undesired neighbor optical signals entering pixels. Also, the desired optical signal can be reflected to the pixel. Therefore, the issue described in the prior art can be improved.

Those skilled in the art will readily observe that numerous modifications and alterations of the device and method may be made while retaining the teachings of the invention.

What is claimed is:

1. An image sensor structure, comprising:
a pixel;
a first metal line;
a second metal line, located under the first metal line;
at least one dummy via, provided between the first metal line and the second metal line, wherein the first metal line and the second metal line are not electrically connected to each other via the dummy via.

2. The image sensor structure of claim 1, wherein the dummy via is electrically connected to one of the first metal line and the second metal line.

3. The image sensor structure of claim 1, wherein the dummy via prevents light entering the pixel.

4. The image sensor structure of claim 1, wherein the dummy via reflects light to enter the pixel.

5. The image sensor structure of claim 1, wherein at least two dummy vias are integrated to form a dummy via side wall.

6. The image sensor structure of claim 1, further comprising at least one via located between the first metal line and the second metal line, wherein one dummy via and one via are integrated to form a dummy via side wall.

7. The image sensor structure of claim 1, further comprising:
a conductive region, located under the second metal line; and
at least one dummy contact, provided between the second metal line and the conductive region, wherein the second metal line and the conductive region are not electrically connected to each other via the dummy contact.

8. The image sensor structure of claim 7, wherein the dummy contact is electrically connected to one of the second metal line and the conductive region.

9. The image sensor structure of claim 7, wherein the dummy contact prevents light entering the pixel.

10. The image sensor structure of claim 7, wherein the dummy contact reflects light to enter the pixel.

11. The image sensor structure of claim 7, wherein the dummy contact is a diffusion region or a poly silicon region.

12. The image sensor structure of claim 7, further comprising at least one contact located between the second metal line and the conductive region, wherein one dummy contact and one contact are integrated to form a dummy contact side wall.

13. An image sensor structure, comprising:
a pixel;
a first metal line;
a second metal line, located under the first metal line;
a conductive region, located under the second metal line; and
at least one dummy contact, provided between the second metal line and the conductive region, wherein the second metal line and the conductive region are not electrically connected to each other via the dummy contact.

14. The image sensor structure of claim 13, wherein the dummy contact is electrically connected to one of the second metal line and the conductive region.

15. The image sensor structure of claim 13, wherein the dummy contact prevents light entering the pixel.

16. The image sensor structure of claim 13, wherein the dummy contact reflects light to enter the pixel.

17. The image sensor structure of claim 13, wherein the dummy contact is a diffusion region or a poly silicon region.

18. The image sensor structure of claim 13, further comprising at least one contact located between the second metal line and the conductive region, wherein one dummy contact and one contact are integrated to form a dummy contact side wall.
